(19) United States
(12) Patent Application Publication
(10) Pub. No.: US 2010/0245271 A1
(43) Pub. Date: Sep. 30, 2010

(54) DISPLAY APPARATUS COMPRISING ALIGNMENT MARK

(75) Inventor: Sang-Hun PARK, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Yongin-city (KR)

(21) Appl. No.: 12/707,854

(22) Filed: Feb. 18, 2010

(30) Foreign Application Priority Data
Mar. 30, 2009 (KR) 10-2009-0026947

(51) Int. Cl. G06F 3/041; G09G 3/00; G09G 3/30

(52) U.S. Cl. 345/173; 345/30; 345/76

(57) ABSTRACT

A flat panel display apparatus is provided, including a substrate; a display unit formed on the substrate, the display unit including a plurality of display elements; a sealing unit formed on an edge of the display unit; an alignment mark unit formed between the display unit and the sealing unit; and an encapsulation substrate encapsulating the display unit and the alignment mark unit, the encapsulation substrate having an alignment mark recognition structure formed in a portion thereof that faces the alignment mark unit.

### CROSS-REFERENCE TO RELATED APPLICATION

This application claims the benefit of Korean Application No. 2009-26947, filed Mar. 30, 2009 in the Korean Intellectual Property Office, the disclosure of which is incorporated herein by reference.

### BACKGROUND OF THE INVENTION

1. Field of the Invention

Aspects of the present invention relate to a display apparatus including an alignment mark, and more particularly, to a display apparatus including an alignment mark that may improve alignment with an exterior member, such as a flexible printed circuit board (FPCB) or a touch screen panel, when the exterior member is coupled with the display apparatus.

2. Description of the Related Art

Flat panel display apparatuses including display units (such as organic light emitting display apparatuses and liquid crystal display apparatuses) include a pad electrode unit which is coupled with an electrode unit of a flexible printed circuit board (FPCB) which transmits an external signal to a display device. The pad electrode unit is required to be precisely aligned with the electrode unit of the FPCB before being coupled thereto. To achieve precise alignment, an alignment mark is generally formed around the pad electrode unit.

FIGS. 1 and 2 are an exploded perspective view and a cross-sectional view, respectively, of components of a flat panel display apparatus, wherein the components are conventionally combined. Referring to FIGS. 1 and 2, the flat panel display apparatus includes a lower substrate 10, an upper substrate 20, an FPCB 30, and a dummy FPCB 40.

A display unit 11 including a plurality of display elements, a sealing unit 12 for sealing the display unit 11, a pad electrode unit 13 coupled to an electrode unit 33 of the FPCB 30, and an alignment mark 14 are formed on the lower substrate 10. The sealing unit 12 is used to seal the lower substrate 10 to the upper substrate 20. The electrode unit 33 of the FPCB 30, which is to be coupled with the pad electrode unit 13 formed on the upper surface of the lower substrate 10, is formed on a lower surface of the FPCB 30.

Conventionally, in the flat panel display apparatus illustrated in FIGS. 1 and 2, first, the lower substrate 10, including a plurality of display elements, and the upper substrate 20 are sealed together by the sealing unit 12. Then the FPCB 30 is coupled to the pad electrode unit 13.

In the conventional art, to increase the precision of alignment of the pad electrode unit 13 on the lower substrate 10 with the electrode unit 33 of the FPCB 30, first, the dummy FPCB 40 is disposed below the lower substrate 10. The dummy FPCB 40 includes an electrode pattern 43 corresponding to the pad electrode unit 13 and an alignment mark 44 corresponding to the alignment mark 14 of the lower substrate 10 is disposed below the lower substrate 10. Thus the lower substrate 10 is first aligned with the dummy FPCB 40 by using the alignment mark 14 of the lower substrate 10 and the alignment mark 44 of the dummy FPCB 40. Next, the FPCB 30 is mounted on a jig J (see FIG. 2), and the jig is moved downward. Thus, the electrode unit 33 of the FPCB 30 is coupled to the pad electrode unit 13 of the lower substrate 10.

In such an alignment process, the precision of alignment of the alignment mark 44 of the dummy FPCB 40 with the alignment mark 14 formed on the lower substrate 10 affects the overall alignment. However, in this alignment process, the degree of alignment of the dummy FPCB 40 with the lower substrate 10 is checked with the naked eye E, and thus an operative error may be generated when performing alignment.

Recently, a touch screen function of inputting a command signal by touching a display screen by means of an indicating device, such as a finger or a pen, is applied to flat panel display apparatuses. To provide this touch screen function, a touch screen panel is attached to the exterior of a flat panel display apparatus, and the attachment of the touch screen panel with the flat panel display apparatus requires an alignment reference. However, the conventional alignment mark 14 loses its function as an alignment reference when the FPCB 30 is coupled to the flat panel display apparatus. Therefore, as described above, an alignment mark that can serve as an alignment reference is required in a process of attaching a touch screen panel to a flat panel display apparatus.

### SUMMARY OF THE INVENTION

Aspects of the present invention provide a display apparatus including an alignment mark, wherein the display apparatus can be precisely aligned with an exterior member, such as a flexible printed circuit board (FPCB) and/or a touch screen panel, when the exterior member is coupled with the display apparatus.

According to an aspect of the present invention, there is provided a flat panel display apparatus including a substrate; a display unit formed on the substrate, the display unit comprising a plurality of display elements; a sealing unit formed on an edge of the display unit; an alignment mark unit formed between the display unit and the sealing unit; and an encapsulation substrate encapsulating the display unit and the alignment mark unit, the encapsulation substrate comprising an alignment mark recognition structure formed in a portion thereof that faces the alignment mark unit.

According to an aspect of the present invention, the alignment mark recognition structure may be formed by etching the encapsulation substrate by a predetermined thickness.

According to an aspect of the present invention, the alignment mark recognition structure may be a lens structure that allows the alignment mark unit to be magnified and recognized.

According to an aspect of the present invention, the alignment mark unit may be formed on a non-emission area formed on an edge of an emission area of the display unit, and formed of a material used to form an uppermost conductive layer of the emission area.

According to an aspect of the present invention, the alignment mark unit may be patterned simultaneously when the uppermost conductive layer is patterned.

According to an aspect of the present invention, the alignment mark unit may be electrically connected to the uppermost conductive layer of the emission area.

According to an aspect of the present invention, the alignment mark unit may be electrically insulated from the uppermost conductive layer of the emission area.

According to an aspect of the present invention, the alignment mark unit may include a pair of alignment marks symmetrical to each other, and the two alignment marks may be respectively arranged at both ends of the non-emission area so as to be symmetrical to each other.

According to an aspect of the present invention, the alignment mark unit may include a single cross-shaped alignment mark, and the alignment mark may be formed at the center of the non-emission area.

According to an aspect of the present invention, the alignment mark may include a horizontal component and a vertical component.

According to an aspect of the present invention, the flat panel display apparatus may further include a pad electrode unit which is formed on an edge of the sealing unit formed on the substrate and comprises a plurality of electrodes.

According to an aspect of the present invention, the flat panel display apparatus may further include a flexible printed circuit board (FPCB) which is coupled to the pad electrode unit.

According to an aspect of the present invention, the flat panel display apparatus may further include an exterior member disposed on the encapsulation substrate.

According to an aspect of the present invention, the exterior member may include an exterior member alignment mark unit formed on a portion thereof that faces the alignment mark unit of the display unit.

According to an aspect of the present invention, the exterior member may include an exterior member alignment mark unit having a pattern corresponding to a pattern of the alignment mark unit of the display unit.

According to an aspect of the present invention, the exterior member may be a touch screen panel.

According to an aspect of the present invention, the flat panel display apparatus may further include a buffer layer formed on the substrate.

According to another aspect of the present invention, there is provided an organic light emitting display apparatus including a substrate; a display unit comprising a plurality of organic light emitting elements each comprising a first electrode layer, an emission layer, and a second electrode layer sequentially formed on the substrate; a sealing unit formed on an edge of the display unit; an alignment mark unit formed on the same level as the second electrode layer and between the display unit and the sealing unit, wherein the alignment mark unit is formed of the same material as a material used to form the second electrode layer; and an encapsulation substrate encapsulating the display unit and the alignment mark unit, the encapsulation substrate comprising an alignment mark recognition structure formed in a portion thereof that faces the alignment mark unit.

According to an aspect of the present invention, the alignment mark recognition structure may be formed by etching the encapsulation substrate by a predetermined thickness.

According to an aspect of the present invention, the alignment mark recognition structure may be a lens structure that allows the alignment mark unit to be magnified and recognized.

According to an aspect of the present invention, the alignment mark unit may be electrically connected to the second electrode layer.

According to an aspect of the present invention, the organic light emitting display apparatus may further include a FPCB which is coupled to the pad electrode unit formed on the edge of the sealing unit on the substrate.

According to an aspect of the present invention, the organic light emitting display apparatus may further include an exterior member which is disposed on the encapsulation substrate and includes an exterior member alignment mark unit formed on a portion thereof that faces the alignment mark unit of the display unit.

According to an aspect of the present invention, the organic light emitting display apparatus may further include an exterior member which is disposed on the encapsulation substrate and includes an exterior member alignment mark unit having a shape corresponding to a shape of the alignment mark unit of the display unit.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is an exploded perspective view schematically illustrating components of a flat panel display apparatus, wherein the components are conventionally combined;

FIG. 2 is a cross-sectional view schematically illustrating the components of the flat panel display apparatus illustrated in FIG. 1 when conventionally combined;

FIG. 3 is an exploded perspective view schematically illustrating components of a flat panel display apparatus according to an embodiment of the present invention;

FIG. 4 is a cross-sectional view schematically illustrating the components of the flat panel display apparatus illustrated in FIG. 3 when combined, according to an embodiment of the present invention;

FIG. 5 is a cross-sectional view schematically illustrating a part of an organic light emitting display apparatus in which a display unit includes an organic light emitting element, according to an embodiment of the present invention;

FIGS. 6A through 6C schematically illustrate various embodiments of an alignment mark unit of the flat panel display apparatus illustrated in FIG. 3; and

FIG. 7 is a cross-sectional view schematically illustrating an alignment mark recognition structure according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

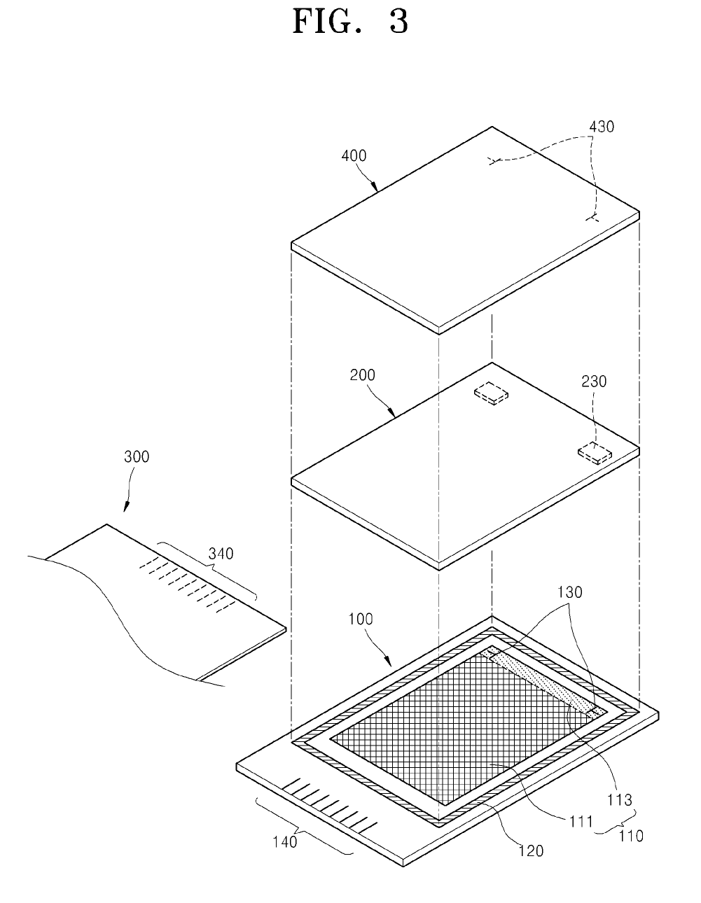

FIG. 3 is an exploded perspective view schematically illustrating a combination of components of a flat panel display apparatus according to an embodiment of the present invention. FIG. 4 is a cross-sectional view schematically illustrating the combination of the components of the flat panel display apparatus illustrated in FIG. 3, according to an embodiment of the present invention. Referring to FIGS. 3 and 4, the flat panel display apparatus includes a substrate 100, an encapsulation substrate 200 for encapsulating a display unit 110 formed on the substrate 100, a flexible printed circuit board (FPCB) 300 joined to an edge of the substrate 100, and an exterior member 400 attached to an upper surface of the encapsulation substrate 200.

The substrate 100 may be formed of a transparent glass material mainly composed of SiO₂. However, the present invention is not limited thereto, and the substrate 100 may be formed of a material such as plastic or metal. A buffer layer (not shown) formed of, for example, SiO₂ and/or SiNₓ may be further formed on the upper surface of the substrate 100 in order to planarize the substrate 100 and prevent impurities from penetrating into the substrate 100.

Various types of display elements (such as organic light emitting elements, LCD elements, etc.) may be included in the display unit 110 on the substrate 100.

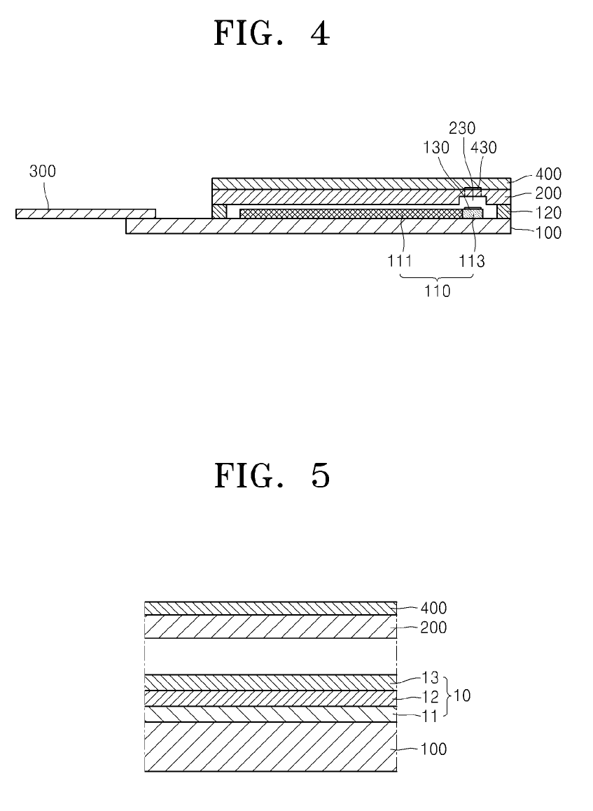

FIG. 5 is a cross-sectional view schematically illustrating an example where the display unit 110 is an organic light emitting display apparatus. Shown specifically is one organic light emitting element 10. The organic light emitting element 10 formed on the substrate 100 includes a first electrode layer 11 and a second electrode layer 13 facing each other, and an emission layer 12 interposed between the first and second electrode layers 11 and 13.

If the organic light emitting display apparatus is a top-emission organic light emitting display apparatus in which images are displayed toward the encapsulation substrate 200, the first electrode layer 11 may be formed of Ag, Mg, Al, Pt, Pd, Au, Ni, Nd, Ir, Cr, or a mixture of two or more of these materials in order to serve as a reflection layer. A transparent conductive material such as ITO, IZO, In₂O₃, or ZnO may be further deposited on an upper surface and/or a lower surface of the reflection layer in order to reduce contact resistance or improve interface characteristics.

If the organic light emitting display apparatus is a passive matrix (PM) organic light emitting display apparatus, the first electrode layer 11 may be formed with strips that are separated from one another at regular intervals. If the organic light emitting display apparatus is an active matrix (AM) organic light emitting display apparatus, the first electrode layer 11 may be formed to correspond to pixels of the organic light emitting element 10. In addition, If the organic light emitting display apparatus is a PM organic light emitting display apparatus, a thin film transistor (TFT) layer including at least one TFT is further included on the substrate 100 below the first electrode layer 11, and the first electrode layer 11 is electrically connected to the TFT layer. The first electrode layer 11 may serve as an anode by being connected to an external terminal (not shown).

The second electrode layer 13 is located above the first electrode layer 11. The second electrode layer 13 may serve as a transmission electrode and may be formed thinly so as to constitute a semitransparent film formed of metal such as Li, Ca, LiF/Ca, LiF/AI, Al, Mg, or Ag. Moreover, a transparent conductive body formed of ITO, IZO, ZnO, or In₂O₃ may be disposed on the metal semitransparent film in order to compensate for a high resistance problem caused by the thinness of the metal semitransparent film. The second electrode layer 13 may serve as a cathode by being connected to an external electrode terminal (not shown).

If the organic light emitting display apparatus is a PM organic light emitting display apparatus, the second electrode layer 13 may be formed with strips that intersect the strips of the first electrode layer 11. If the organic light emitting display apparatus is an AM organic light emitting display apparatus, the second electrode layer 13 may be formed to correspond to the pixels of the organic light emitting element 10. If the organic light emitting display apparatus is an AM organic light emitting display apparatus, the second electrode layer 13 may be formed on the entire active area where an image is displayed, and an alignment mark unit 130 according to the present embodiment may be formed of a conductive material used to form the second electrode layer 13, simultaneously with the formation of the second electrode layer 13. The simultaneous formation of the alignment mark unit 130 and the second electrode layer 13 will be described later. The first electrode layer 11 and the second electrode layer 13 may have opposite polarities.

The emission layer 12 interposed between the first and second electrode layers 11 and 13 emits light by electrical operations of the first electrode layer 11 and the second electrode layer 13. The emission layer 12 may be formed of a small molecular organic material or a polymer organic material. When the emission layer 12 is formed of a small molecular organic material, a hole transport layer, a hole injection layer, etc. (not shown) are stacked on the emission layer 12 in a direction toward the first electrode layer 11, and an electron transport layer, an electron injection layer, etc. (not shown) are stacked on the emission layer 12 in a direction toward the second electrode layer 13. Of course, various layers other than the hole injection layer, the hole transport layer, the electron transport layer, and the electron injection layer may be stacked as occasion demands. When the emission layer 12 is formed of a polymer organic material, only a hole transport layer (not shown) may be stacked on the emission layer 12 in a direction toward the first electrode layer 11.

As shown in FIG. 3, the display unit 110 includes an emission area 111 in which display elements (such as the element 10 of FIG. 5) emit light to display an image, and a non-emission area 113 in which dummy pixels or the like support the light emission of the display elements or perform a test.

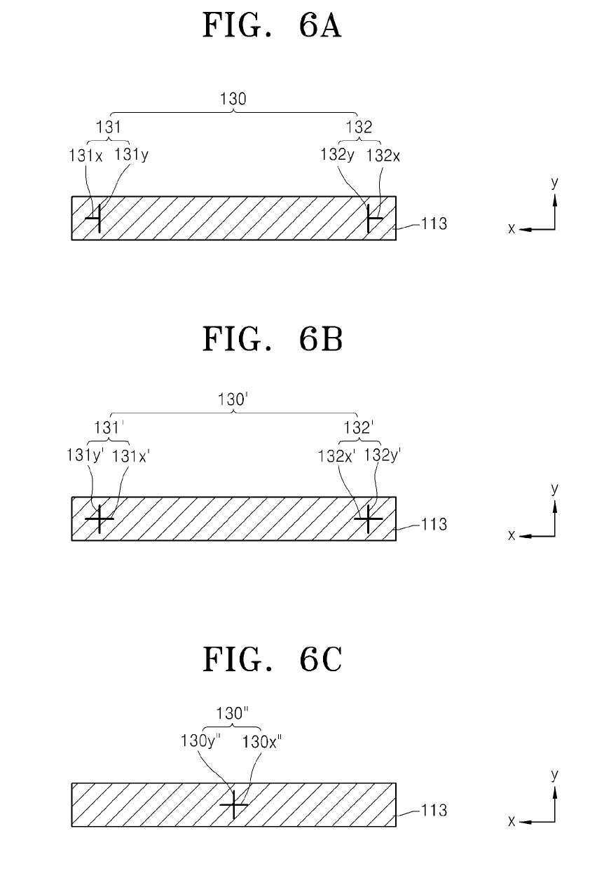

The alignment mark unit 130 is formed on the non-emission area 113. FIGS. 6A through 6C schematically illustrate various embodiments of the alignment mark unit 130 of the flat panel display apparatus illustrated in FIG. 3. Referring to FIG. 6A, the alignment mark unit 130 includes a pair of alignment marks 131 and 132 which are symmetrical to each other, according to an embodiment of the present invention. The alignment marks 131 and 132 are respectively arranged at edges of the non-emission area 113 so as to be symmetrical to each other. The alignment mark 131 has a shape of a half-cross having a horizontal component 131x and a vertical component 131y. The alignment mark 132 has a shape of a half-cross having a horizontal component 132x and a vertical component 132y.

Referring to an embodiment shown in FIG. 6B, an alignment mark unit 130′ includes a pair of alignment marks 131′ and 132′ which are symmetrical to each other, according to an embodiment of the present invention. The alignment marks 131′ and 132′ are respectively arranged at edges of the non-emission area 113 so as to be symmetrical to each other. The alignment mark 131′ has a shape of a cross having a horizontal component 131x′ and a vertical component 131y′. The alignment mark 132′ has a shape of a cross having a horizontal component 132x′ and a vertical component 132y′.

Referring to an embodiment shown in FIG. 6C, an alignment mark unit 130″ includes a single cross-shaped alignment mark including a horizontal component 130x″ and a vertical component 130y″, wherein the cross-shaped alignment mark is formed at the center of the non-emission area 113, according to an embodiment of the present invention.

The above-described shapes and arrangements of the alignment mark unit 130 are only exemplary embodiments, and thus the present invention is not limited thereto. In other words, various changes in the alignment mark unit 130 may be made. Although it is illustrated in the drawings that the alignment mark units 130, 130′ and 130″ are formed on only the non-emission area 113, the non-emission area 113 may be disposed at locations other than the location illustrated in FIGS. 3 and 4, and thus the locations and the number of alignment mark units may vary.

As shown in FIG. 3, alignment mark unit 130 is formed of the same material as a material used to form an uppermost conductive layer included in the emission area 111 of the display unit 110. In the case of the organic light emitting element 10 of FIG. 5, the alignment mark unit 130 is formed of the same material as a material used to form the second electrode layer 13 corresponding to the uppermost conductive layer of the non-emission area 113, and is patterned simultaneously when the second electrode layer 13 is patterned. The alignment mark unit 130 may be formed to be electrically insulated from the second electrode layer 13.

The alignment mark unit 130 may not be electrically insulated from the second electrode layer 13. That is, the alignment mark unit 130 may be electrically connected to the second electrode layer 13. In this case, the alignment mark unit 130 forms an equipotential surface together with the second electrode layer 13, and thus static electricity due to a potential difference between the second electrode layer 13 and the alignment mark unit 130 may be prevented.

The sealing unit 120 is arranged around and spaced apart from the display unit 110 on which the alignment mark unit 130 is formed. The sealing unit 120 may be formed of a material such as frit glass, polymer epoxy resin, or the like. By coupling the substrate 100 with the encapsulation substrate 200 by using the sealing unit 120, the display unit 110 is shielded from external humidity or oxygen. The encapsulation substrate 200 may be a transparent substrate.

An alignment mark recognition structure 230 is formed at a location on the encapsulation substrate 200 that corresponds to a location on the display unit 110 where the alignment mark unit 130 is formed. In other words, the alignment mark recognition structure 230 is formed in a portion of the encapsulation substrate 200 directly over the alignment mark unit 130 so that the alignment mark unit 130 can be recognized when a user views the display unit 110 from a position above the encapsulation substrate 200. While shown as being substantially perpendicular to the surface of the encapsulation substrate 200 such that the alignment mark unit 130 is aligned with the alignment mark recognition structure 230 when viewed from above the alignment mark recognition structure 230, it is understood that the alignment could be performed where the alignment mark recognition structure 230 aligns at a non-perpendicular angle with the alignment mark unit 130.

The alignment mark recognition structure 230 may be formed by etching the encapsulation substrate 200 by a predetermined thickness. In other words, the visibility of the alignment mark unit 130 through the encapsulation substrate 200 may be increased by reducing the thickness of the portion of the encapsulation substrate 200 that faces the alignment mark unit 130.

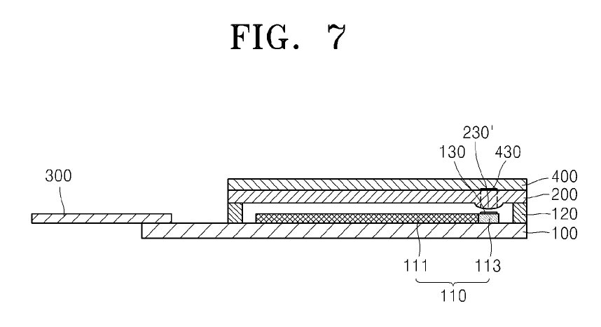

FIG. 7 is a cross-section view schematically illustrating an alignment mark recognition structure 230′ according to another embodiment of the present invention. Referring to FIG. 7, the alignment mark recognition structure 230′ according to the present embodiment is formed in a portion of the encapsulation substrate 200 which is directly above the alignment mark unit 130, and has a lens structure. For example, the alignment mark recognition structure 230′ may have a convex lens structure in order to increase the visibility of the alignment mark unit 130. The alignment mark recognition structure 230′ may be formed by etching the encapsulation substrate 200, or by patterning a lens forming material coated on the encapsulation substrate 200. However, it is understood that the lens structure need not be provided in all aspects.

The alignment mark recognition structures 230 or 230′ are formed in the encapsulation substrate 200 so that the numbers of alignment mark recognition structures 230 or 230′ correspond to the number of alignment mark units 130. In other words, when a single alignment mark unit 130 is formed, a single alignment mark recognition structure 230 or 230′ is formed. When a plurality of alignment mark units 130 are formed, a corresponding plurality of alignment mark recognition structures 230 or 230′ are formed to face the alignment mark units 130.

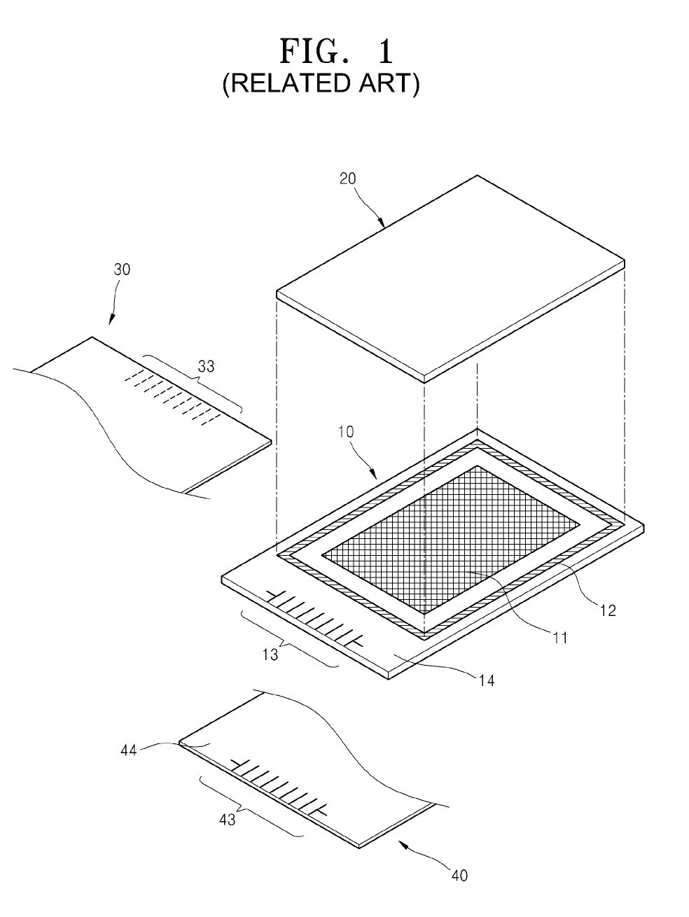

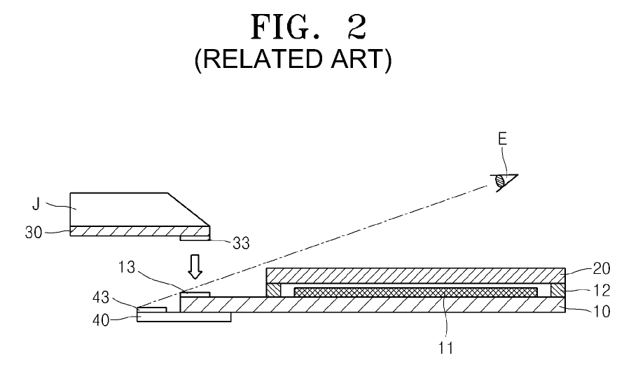

As shown in FIG. 3, the pad electrode unit 140 is electrically connected to the display unit 110 and is formed on an edge of the sealing unit 120 on the substrate 100. A plurality of electrodes that constitute the pad electrode unit 140 are formed to be parallel to the vertical component (that is, a component in the y direction) of the alignment mark unit 130 (see FIGS. 6A to 6C). This structure is formed because the pad electrode unit 140 is first formed on the substrate 100 and then the alignment mark unit 130 is formed during the formation of the uppermost conductive layer of the display unit 110 by using a mask patterned so that vertical component marks of the alignment mark unit 130 are parallel to the electrodes of the pad electrode unit 140. In contrast with the conventional art where the dummy FPCB 40 illustrated in FIGS. 1 and 2 serves as an alignment reference, the alignment mark unit 130 formed in this way may serve as an alignment reference when the FPCB 300 is coupled with the pad electrode unit 140. Thus, the alignment mark unit 130 formed by patterning using a mask may significantly improve the alignment precision as compared with the conventional art in which the alignment is checked with the naked eye.

The FPCB 300, which transmits an external signal to the display unit 110 is coupled to the pad electrode unit 140. An electrode unit 340 of the FPCB 300 is coupled with the pad electrode unit 140 on the substrate 100 such as to correspond to the pad electrode unit 140. Since the FPCB 300 is installed on a jig (not shown) as described above in relation to FIG. 2, the electrode unit 340 of the FPCB 300 is coupled to the pad electrode unit 140 of the substrate 100 by a downward motion of the jig.

The exterior member 400 is disposed on the encapsulation substrate 200. The exterior member 400 may be a touch screen panel, a protection case for a display apparatus, or the like. An exterior member alignment mark unit 430 is formed on a portion of the exterior member 400 that corresponds to the area on the display unit 110 where the alignment mark unit 130 is formed. The exterior member alignment mark unit 430 may have a shape corresponding to the shape of the alignment mark unit 130 of the display unit 110. For example, if a pair of half-cross alignment mark units 230 are formed on both ends of the non-emission area 113 of the display unit 110 so as to be symmetrical to each other as illustrated in FIG. 3, a pair of half-cross-shaped exterior member alignment marks constituting exterior member alignment mark units 430 are formed at edges of the exterior member 400 so as to be symmetrical to each other. While shown as being substantially perpendicular to the surface of the encapsulation substrate 200 such that the alignment mark unit 130 and the exterior member alignment mark unit 430 are aligned with the alignment mark recognition structure 230 when viewed from above the alignment mark recognition structure 230, it is understood that the alignment could be performed where the alignment mark recognition structure 230 aligns at a non-perpendicular angle with the alignment mark unit 130 and the exterior member alignment mark unit 430.

When an exterior member and a flat panel display apparatus are aligned with each other by using an alignment mark unit of a display unit and an exterior member alignment mark unit as an alignment reference, an alignment mark recognition structure formed in an encapsulation substrate increases the visibility of the alignment mark unit through the encapsulation substrate, thereby significantly increasing the precision of the alignment. Therefore, in a flat panel display apparatus according to aspects of the present invention as described above, an alignment mark is formed on a display unit, and an alignment mark recognition structure is formed in a portion of an encapsulation substrate which faces the alignment mark. Thus, without the need for any special aligning device, an FPCB may be aligned with the flat panel display apparatus and an exterior member may be aligned with the flat panel display apparatus. Consequently, the precision of the alignment may be significantly improved.

Although a few embodiments of the present invention have been shown and described, it would be appreciated by those skilled in the art that changes may be made in this embodiment without departing from the principles and spirit of the invention, the scope of which is defined in the claims and their equivalents.

1. A flat panel display apparatus comprising:
a substrate;
a display unit formed on the substrate, the display unit comprising a plurality of display elements;
a sealing unit formed on the substrate surrounding an edge of the display unit;
an alignment mark unit formed between the display unit and the sealing unit; and
an encapsulation substrate sealed to the substrate by the sealing unit and encapsulating the display unit and the alignment mark unit, the encapsulation substrate comprising an alignment mark recognition structure formed in a portion thereof that faces the alignment mark unit.

2. The flat panel display apparatus of claim 1, wherein the alignment mark recognition structure is formed by etching the encapsulation substrate by a predetermined thickness.

3. The flat panel display apparatus of claim 1, wherein the alignment mark recognition structure comprises a lens structure that allows the alignment mark unit to be magnified and recognized.

4. The flat panel display apparatus of claim 1, wherein the display unit comprises an emission area which emits light from the display elements, and a non-emission area at an edge of the emission area, and the alignment mark unit is formed on the non-emission area of a material used to form an uppermost conductive layer of the display elements in the emission area.

5. The flat panel display apparatus of claim 4, wherein the alignment mark unit is patterned simultaneously when the uppermost conductive layer is patterned.

6. The flat panel display apparatus of claim 4, wherein the alignment mark unit is electrically connected to the uppermost conductive layer of the emission area.

7. The flat panel display apparatus of claim 4, wherein the alignment mark unit is electrically insulated from the uppermost conductive layer of the emission area.

8. The flat panel display apparatus of claim 4, wherein the alignment mark unit comprises a pair of alignment marks symmetrical to each other, and the two alignment marks are respectively arranged at both ends of the non-emission area so as to be symmetrical to each other.

9. The flat panel display apparatus of claim 4, wherein:
the alignment mark unit comprises a single cross-shaped alignment mark; and
the alignment mark is formed at a center of the non-emission area.

10. The flat panel display apparatus of claim 8, wherein the alignment mark comprises a horizontal component and a vertical component.

11. The flat panel display apparatus of claim 4, further comprising a pad electrode unit formed on the substrate at an edge of the sealing unit and comprising a plurality of electrodes.

12. The flat panel display apparatus of claim 11, further comprising a flexible printed circuit board (FPCB) which is coupled to the pad electrode unit.

13. The flat panel display apparatus of claim 1, further comprising an exterior member disposed on the encapsulation substrate such that the encapsulation substrate is between the substrate the exterior member.

14. The flat panel display apparatus of claim 13, wherein the exterior member comprises an exterior member alignment mark unit formed on a portion thereof that faces the alignment mark unit of the display unit through the alignment mark recognition structure.

15. The flat panel display apparatus of claim 13, wherein the exterior member comprises an exterior member alignment mark unit having a pattern corresponding to a pattern of the alignment mark unit of the display unit.

16. The flat panel display apparatus of claim 13, wherein the exterior member comprises a touch screen panel.

17. The flat panel display apparatus of claim 1, further comprising a buffer layer formed on the substrate.

18. An organic light emitting display apparatus comprising:
a substrate;
a display unit comprising a plurality of organic light emitting elements, each organic light emitting element comprising a first electrode layer, an emission layer, and a second electrode layer sequentially formed on the substrate;
a sealing unit formed on the substrate and surrounding an edge of the display unit;
an alignment mark unit formed on a same plane above the substrate as the second electrode layer and is disposed between the display unit and the sealing unit, wherein the alignment mark unit is formed of a same material as a material used to form the second electrode layer; and
an encapsulation substrate sealed to the substrate by the sealing unit and encapsulating the display unit and the alignment mark unit, the encapsulation substrate comprising an alignment mark recognition structure formed in a portion thereof that faces the alignment mark unit.

19. The organic light emitting display apparatus of claim 18, wherein the alignment mark recognition structure is formed by etching the encapsulation substrate by a predetermined thickness.

20. The organic light emitting display apparatus of claim 18, wherein the alignment mark recognition structure comprises a lens structure that allows the alignment mark unit to be magnified and recognized.

21. The organic light emitting display apparatus of claim 18, wherein the alignment mark unit is electrically connected to the second electrode layer.

22. The organic light emitting display apparatus of claim 18, further comprising:
a pad electrode unit formed on the substrate at an edge of the sealing unit and comprising a plurality of electrodes; and
a flexible printed circuit board (FPCB) which is coupled to the pad electrode unit.

23. The organic light emitting display apparatus of claim 18, further comprising an exterior member which is disposed on the encapsulation substrate and comprises an exterior member alignment mark unit formed on a portion thereof that faces the alignment mark unit of the display unit through the alignment mark recognition structure.

24. The organic light emitting display apparatus of claim 18, further comprising an exterior member which is disposed on the encapsulation substrate and comprises an exterior member alignment mark unit having a shape corresponding to a shape of the alignment mark unit of the display unit.

25. The flat panel display apparatus of claim 9, wherein the alignment mark comprises a horizontal component and a vertical component.

26-32. (canceled)

33. A display apparatus comprising:
a display unit comprising a plurality of display elements;
an alignment mark unit formed adjacent the display unit; and
an encapsulation substrate sealed to the display unit such that the display unit and the alignment mark unit within a sealed area which seals the display unit and the alignment mark unit from external humidity or oxygen, the encapsulation substrate further comprising an alignment mark recognition structure facing the alignment mark unit within the sealed area.

34. The display apparatus of claim 33, further comprising an external panel comprising an additional alignment mark unit, wherein the encapsulation substrate is disposed between the display unit and the external panel and the additional alignment mark unit is aligned with the alignment mark via the alignment mark recognition structure.

35. The display apparatus of claim 34, wherein the external panel comprises a touch screen panel.
